(19) United States
(12) Patent Application Publication
(10) Pub. No.: US 2023/0128033 A1
(43) Pub. Date: Apr. 27, 2023

(54) METHOD FOR ION IMPLANTATION IN A SEMICONDUCTOR WAFER

(71) Applicant: STMicroelectronics (Crolles 2) SAS, Crolles (FR)

(72) Inventors: Julien BORREL, Le Versoud (FR); Alexis GAUTHIER, Meylan (FR); Fanny HILARIO, Grenoble (FR); Ludovic BERTHIER, Les Adrets (FR); Paul DUMAS, Grenoble (FR); Edoardo BREZZA, Grenoble (FR)

(73) Assignee: STMicroelectronics (Crolles 2) SAS, Crolles (FR)

(21) Appl. No.: 17/964,350

(22) Filed: Oct. 12, 2022

(30) Foreign Application Priority Data
Oct. 26, 2021 (FR) 2111357

(51) Int. Cl. H01L 21/266; H01L 29/06

(52) U.S. Cl. CPC H01L 21/266; H01L 29/0607

(57) ABSTRACT

According to one aspect provision is made of a method for ion implantation in a semiconductor wafer placed in an implantation chamber under vacuum, the semiconductor wafer having an integrated circuit area and a peripheral area around this integrated circuit area, the ion implantation allowing to apply a doping in regions, called implantation regions, of the integrated circuit area, the method comprising: forming a photosensitive resin coating serving as a mask on the semiconductor wafer, then forming openings in the photosensitive resin coating at said implantation regions of the integrated circuit area and at least at one region of the peripheral area, then implanting ions in the semiconductor wafer.

### BACKGROUND

### Technical Field

Embodiments and implementations relate to the manufacture of integrated circuits, and more particularly to a method for ion implantation in a semiconductor wafer.

### Description of the Related Art

Ion implantation in a semiconductor wafer is used for manufacturing integrated circuit(s) in this semiconductor wafer. Ion implantation allows dopants to be introduced into this semiconductor in order to modify its conductivity properties.

Ion implantation doping is performed in an implantation chamber under vacuum. Doping involves accelerating ions with an electric field using an implantation machine to impart enough energy to the ions to enter the semiconductor wafer to be doped.

Accelerating an ion increases its kinetic energy so that the ion can sink deeper into the semiconductor wafer.

Once implanted into the semiconductor wafer, the dopants are subjected to a heat treatment necessary for their electrical activation. Each dopant then creates a charge carrier (hole or electron depending on whether it is a P-type or N-type dopant) thus locally modifying the conductivity of the semiconductor wafer.

The amount of implanted dopants is measured using a Faraday cup. During ion implantation, the pressure in the implantation chamber is also monitored to ensure that it does not exceed a predefined threshold to at least substantially maintain the vacuum in the implantation chamber.

To select the regions of the semiconductor wafer to be doped, a mask formed from a photosensitive resin coating should be used. Photosensitive resin generally consists of carbon chains made up of carbon and hydrogen atoms. For example, the mask comprises solid areas allowing to prevent implantation of the ions in the regions of the semiconductor wafer disposed under the solid parts of the mask. The mask also comprises openings allowing the implantation of ions in the regions, called the implantation region, of the semiconductor wafer disposed at these openings.

However, during implantation, the flow of ions emitted can damage the photosensitive resin of the mask. For example, the ions emitted can break the bonds between the atoms of the photosensitive resin. The carbon and hydrogen atoms are then degassed (that is to say expelled) from the resin in the implantation chamber due to the energy transmitted thereto. The pressure in the implantation chamber then increases. For example, the start of implantation can lead to a high peak in carbon and hydrogen degassing.

The degassed atoms can then react with the implantation ions which can then lose their charge. Certain implanted ions are thus not counted by the Faraday cup. As a result, the amount of dopants actually implanted in the semiconductor wafer can then differ by a few percent relative to the amount initially targeted.

Moreover, the degassing of the resin degrades the vacuum of the implantation chamber. When the pressure in the chamber exceeds said predefined threshold, the implantation machine may stop, and therefore delay the manufacture of the integrated circuit. The predefined threshold may be exceeded for example at the time of the degassing peak at the start of implantation.

A pumping system is used to maintain a high vacuum in the implantation machine throughout the implantation method. However, such a pumping system may not be sufficient to react quickly to the rapid rise in pressure at the time of the degassing peak.

One solution to reduce the degassing of atoms from the resin is to reduce the ion beam current. Nevertheless, this solution increases the implantation time, and therefore the time and cost of manufacturing the integrated circuit.

### BRIEF SUMMARY

The disclosure provides an ion implantation solution in a semiconductor wafer, which is simple and inexpensive to implement. This solution should reduce the intensity of the degassing, while ensuring good doping of the semiconductor wafer.

According to an aspect, provision is made of a method for ion implantation in a semiconductor wafer placed in an implantation chamber under vacuum, the semiconductor wafer having an integrated circuit area and a peripheral area around this integrated circuit area, the ion implantation allowing to apply a doping in at least one region, called the implantation region, of the integrated circuit area, the method comprising:
forming a photosensitive resin coating serving as a mask on the semiconductor wafer, the photosensitive resin coating being applied to the integrated circuit area and to the peripheral area, then
forming an opening in the photosensitive resin coating at said at least one implantation region of the integrated circuit area, then
implanting ions in the semiconductor wafer,
the method further comprising, prior to said ion implantation, a formation of an opening in the photosensitive resin coating at least at one region of the peripheral area so as to reduce a covering surface of the photosensitive resin coating on the semiconductor wafer.

The peripheral area is an area used only to facilitate the manufacture of the integrated circuit. This peripheral area can be useful for the implementation of etchings, mechanical-chemical polishing or for making cutting paths. Said at least one region of the peripheral area above which an opening is formed is advantageously a region devoid of electrical connections.

The openings in the photosensitive resin coating are formed at regions of the peripheral area wherein it is possible to implant ions without having any impact subsequently in the manufacture of the integrated circuit.

Reducing degassing allows to reduce the interactions between the degassed atoms and the ions in the implantation beam. This allows to guarantee a good counting of the ions by the Faraday cup, so as to obtain an integrated circuit conforming to that expected.

Such a method is adapted for high power installations, for example greater than 1000 W.

The covering surface of the photosensitive resin coating, after said formation of an opening at least at one region of the peripheral area, is sufficiently small to reduce degassing of atoms of the photosensitive resin coating during said implantation of ions so that the pressure in the implantation chamber remains below a given threshold during this ion implantation.

Such a method allows to reduce the covering surface of the mask to reduce degassing of the mask during ion implantation. For example, during ion implantation, the photosensitive resin surface of the mask exposed to the ions is sufficiently limited so that the pressure in the chamber remains below said threshold to avoid stopping the implantation machine.

In an embodiment, the formation of the opening at said at least one implantation region of the integrated circuit area and the formation of the opening at said at least one region of the peripheral area are carried out simultaneously. Such a method has the advantage of not increasing the manufacturing time of the integrated circuit.

In an embodiment, the covering surface of the photosensitive resin coating, after having formed said openings at said at least one implantation region of the integrated circuit area and at said at least one region of the peripheral area, is less than 75% relative to a total surface of the semiconductor wafer.

In an embodiment, during said ion implantation, the ions are counted using a Faraday cup, said ion implantation ending when the number of counted ions reaches a predefined threshold number.

In an embodiment, said at least one doped region of the peripheral area and said at least one implantation region of the integrated circuit area are doped at a dose greater than or equal to 1×10¹⁵ atoms/cm².

According to another aspect provision is made of a semiconductor device including an integrated circuit area and a peripheral area around said integrated circuit area, the peripheral area comprising at least one doped region of the same nature as at least one doped implantation region of the integrated circuit area.

Thus, provision is made of a semiconductor device obtained from a semiconductor wafer for which an implantation method as described above has been implemented.

In an embodiment, said at least one doped region of the peripheral area is devoid of electrical connections.

In an embodiment, said at least one doped region of the peripheral area and said at least one implantation region of the integrated circuit area have a dopant concentration greater than or equal to 1×10²⁰ atoms/cm³.

### BRIEF DESCRIPTION OF THE SEVERAL VIEWS OF THE DRAWINGS

Other advantages and features of the disclosure will become apparent upon examining the detailed description of implementations and embodiments, which are in no way limiting, and of the appended drawings wherein:

FIG. 1 illustrates an ion implantation method;

FIG. 2 illustrates, in a sectional view, a wafer;

FIG. 3 illustrates a semiconductor wafer placed in an implantation chamber CHI;

FIG. 4 illustrates a sectional view of a result of formation of a photosensitive resin coating on a semiconductor wafer;

FIG. 5 illustrates a sectional view of a result of formation of openings in a photosensitive resin coating;

FIG. 6 illustrates using a semiconductor wafer can to obtain a semiconductor device.

### DETAILED DESCRIPTION

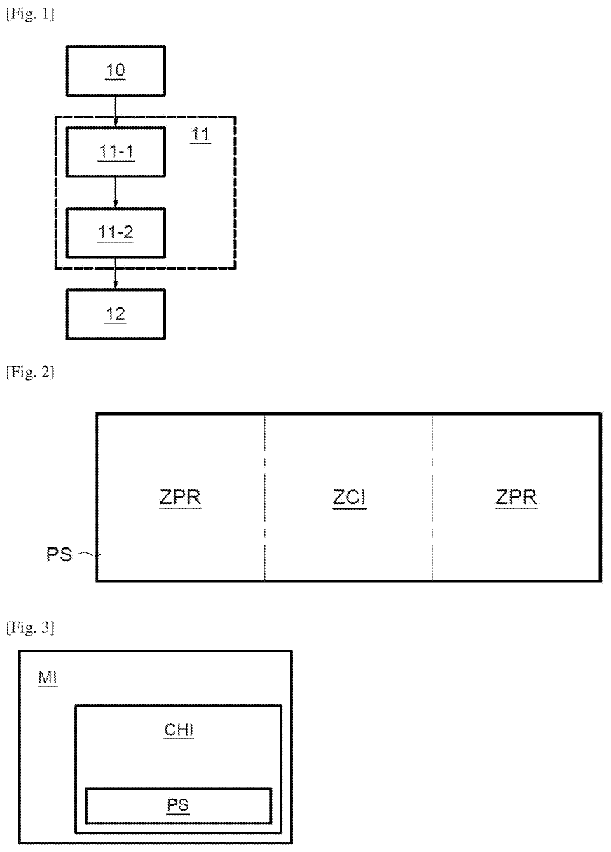

FIG. 1 illustrates an ion implantation method according to an embodiment.

The method comprises obtaining 10 a semiconductor wafer PS. This semiconductor wafer is used to manufacture an integrated circuit. As illustrated in FIG. 2 in a sectional view, the wafer comprises an integrated circuit area ZCI dedicated to forming components of the integrated circuit, and a peripheral area ZPR around said integrated circuit area ZCI. This peripheral area ZPR is not used to form components of the integrated circuit but is useful for implementing the manufacture of the integrated circuit. For example, the peripheral area ZPR is used only to facilitate the manufacture of the integrated circuit. This peripheral area can be useful for the implementation of etchings, mechanical-chemical polishing or for making cutting paths.

Here, for the purposes of understanding, the semiconductor wafer comprises only a single integrated circuit area, and a single peripheral area surrounding the integrated circuit area. Nevertheless, it is possible to provide a semiconductor wafer PS comprising several integrated circuit areas to form several integrated circuits and several peripheral areas around these integrated circuit areas. The peripheral area can also only partially surround the integrated circuit area.

As shown in FIG. 3, the semiconductor wafer PS is placed in an implantation chamber CHI under vacuum of an implantation machine MI. For example, the implantation machine MI comprises a pumping system (not shown) allowing to evacuate the implantation chamber CHI. The implantation machine MI is configured to emit an ion beam into the implantation chamber CHI in the direction of the semiconductor wafer PS to perform ion implantation in the semiconductor wafer PS. The ion implantation in the semiconductor wafer PS allows doping to be applied to regions, called implantation regions, of the integrated circuit area ZCI to form components of the integrated circuit.

Before performing the implantation, the method comprises forming a mask 11 on the semiconductor wafer PS for ion implantation. The mask MSK then allows to select the implantation regions to be doped.

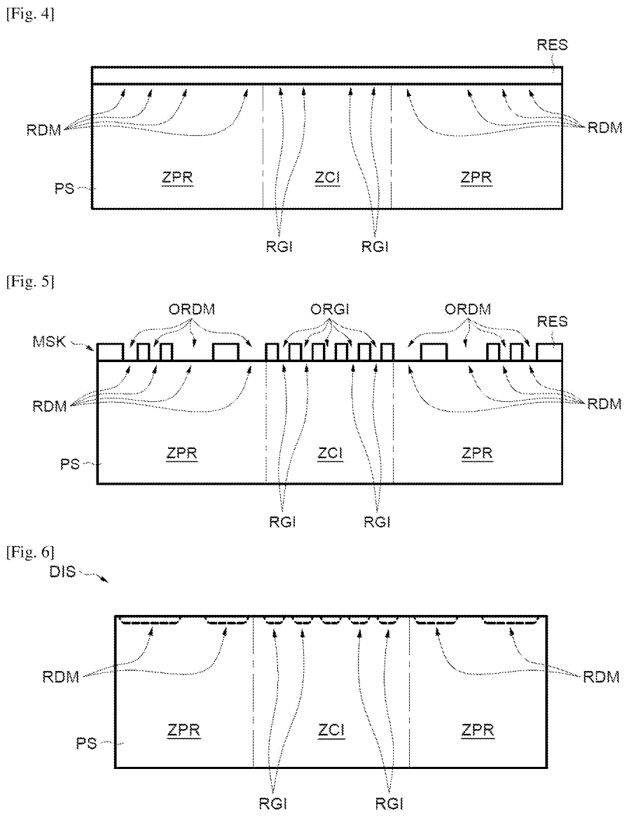

For example, the formation 11 of the mask MSK comprises a formation 11-1 of a photosensitive resin coating RES on the semiconductor wafer PS. FIG. 4 illustrates a sectional view of a result of the formation 11-1 of the photosensitive resin coating RES on the semiconductor wafer PS. The formation of the mask MSK also comprises forming 11-2 openings ORGI and ORDM in the photosensitive resin coating at said implantation regions RGI (for the openings ORGI) of the integrated circuit area ZCI and at least at one region RDM (for the openings ORDM) of the peripheral area ZPR. FIG. 5 illustrates a sectional view of a result of the formation 11-2 of the openings ORGI, ORDM in the photosensitive resin coating.

For example, the openings ORDM are formed at regions of the peripheral area ZPR wherein it is possible to implant ions without having any impact subsequently in the manufacture of the integrated circuit. The openings ORDM formed at the peripheral area ZPR allow to reduce the covering surface of the photosensitive resin coating RES. It is important to try to form as many openings ORDM as possible at the peripheral area ZPR to minimize the covering surface of the photosensitive resin coating RES. For example, the covering surface of the photosensitive resin coating RES is below a threshold.

For example, openings ORDM are formed at dummy regions of the peripheral area. These dummy regions are regions which do not participate in any of the elements of the integrated circuit but which are useful for homogenizing a surface density of the semiconductor wafer at the integrated circuit. These regions RDM are therefore devoid of electrical connections.

It is also possible to form openings ORDM at regions RDM of the peripheral area ZPR in a seal ring. For example, the openings ORDM are ring-shaped and surround openings ORGI. The seal ring serves as a protective barrier between the integrated circuit and the cutting paths on the semiconductor wafer. The seal ring prevents pollution of the integrated circuit by polluting particles resulting from the cutting of the semiconductor wafer along the cutting paths.

The formation of the openings ORDM at the peripheral area ZPR is carried out simultaneously with the formation of the openings ORGI at the integrated circuit area ZCI. Thus, the formation of the openings ORDM at the peripheral area ZPR does not increase the manufacturing time of the integrated circuit.

The method then comprises an implantation of ions 12 into the semiconductor wafer. The ions are then implanted in the regions of the wafer located under the openings of the mask. The photosensitive resin coating then prevents ions from reaching the regions of the semiconductor wafer covered by this coating RES. The regions RDM of the peripheral area ZPR and the regions RGI of the integrated circuit area ZCI can be doped at a dose greater than or equal to 1×10¹⁵ atoms/cm², so as to obtain a dopant concentration greater than or equal to 1×10²⁰ atoms/cm³ in the regions RDM and RGI.

Ion implantation in the semiconductor wafer allows doping to be applied to said implantation regions RGI of the integrated circuit area ZCI to form integrated circuit components.

Moreover, the fact of implanting ions in the regions RDM of the peripheral area ZPR under the openings of the mask does not interfere with the manufacture of the integrated circuit.

Furthermore, the fact of reducing the covering surface of the mask MSK by means of the openings ORDM formed above the peripheral area ZPR of the wafer can reduce degassing of photosensitive resin atoms during ion implantation. Thus, the pressure in the chamber then remains limited and does not cause a shutdown of the implantation machine that may occur when the pressure in the chamber is greater than a given threshold.

During said ion implantation, the ions are counted using a Faraday cup. Ion implantation ends when the number of counted ions reaches a predefined threshold number. The reduction in degassing reduces the reactions between the degassed atoms and the implantation ions causing the charge of the implantation ions to be lost. Thus, said amount of ions counted by the Faraday cup corresponds to the amount of ions implanted in the implantation regions of the integrated circuit area.

Such a method is adapted for high power installations, for example greater than 1000 W.

The semiconductor wafer can then be used to obtain a semiconductor device DIS, as illustrated in FIG. 6. The semiconductor device DIS includes the integrated circuit area ZCI and at least part of the peripheral area ZPR. The peripheral area ZPR then has at least one doped region RDM of the same nature as at least one implantation region RGI of the integrated circuit area ZCI.

A method for ion implantation in a semiconductor wafer (PS) placed in an implantation chamber (CHI) under vacuum, the semiconductor wafer (PS) having an integrated circuit area (ZCI) and a peripheral area (ZPR) around this integrated circuit area (ZCI), the ion implantation allowing to apply a doping in at least one region, called the implantation region (RGI), of the integrated circuit area, the method may be summarized as including forming (11-1) a photosensitive resin coating (RES) serving as a mask on the semiconductor wafer (PS), the photosensitive resin coating (RES) being applied to the integrated circuit area (ZCI) and to the peripheral area (ZPR), then forming (11-2) an opening in the photosensitive resin coating (RES) at said at least one implantation region (RGI) of the integrated circuit area, then implanting ions (12) in the semiconductor wafer (PS), the method further including, prior to said ion implantation, a formation (11-2) of an opening in the photosensitive resin coating (RES) at least at one region (RDM) of the peripheral area so as to reduce a covering surface of the photosensitive resin coating (RES) on the semiconductor wafer (PS).

The covering surface of the photosensitive resin coating, after said formation of an opening at least at one region of the peripheral area, may be sufficiently small to reduce degassing of atoms of the photosensitive resin coating (RES) during said implantation of ions so that the pressure in the implantation chamber (CHI) remains below a given threshold during this ion implantation.

The formation of the opening (ORGI) at said at least one implantation region (RGI) of the integrated circuit area (ZCI) and the formation of the opening (ORDM) at said at least one region (RDM) of the peripheral area (ZPR) may be carried out simultaneously.

The covering surface of the photosensitive resin coating, after having formed said openings (ORGI, ORDM) at said at least one implantation region (RGI) of the integrated circuit area (ZCI) and at said at least one region (RDM) of the peripheral area (ZPR), may be less than 75% relative to a total surface of the semiconductor wafer.

During said ion implantation (12), the ions may be counted using a Faraday cup, said ion implantation ending when the number of counted ions reaches a predefined number.

Said at least one doped region (RDM) of the peripheral area (ZPR) and said at least one implantation region (RGI) of the integrated circuit area (ZCI) may be doped at a dose greater than or equal to 1×10¹⁵ atoms/cm².

A semiconductor device including an integrated circuit area (ZCI) and a peripheral area (ZPR) around said integrated circuit area, the peripheral area (ZPR) may be summarized as including at least one doped region (RDM) of the same nature as at least one doped implantation region (RGI) of the integrated circuit area.

Said at least one doped region (RGM) of the peripheral area (ZPR) may be devoid of electrical connections.

Said at least one doped region (RDM) of the peripheral area (ZPR) and said at least one implantation region (RGI) of the integrated circuit area (ZCI) may have a dopant concentration greater than or equal to 1×10²⁰ atoms/cm³.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for ion implantation in a semiconductor wafer placed in an implantation chamber under vacuum, the semiconductor wafer having an integrated circuit area and a peripheral area around this integrated circuit area, the ion implantation allowing to implant ions in an implantation region of the integrated circuit area, the method comprising:
forming a photosensitive resin coating as a mask on the semiconductor wafer, the photosensitive resin coating being applied to the integrated circuit area and to the peripheral area;
forming an opening in the photosensitive resin coating at the implantation region of the integrated circuit area and an opening in the photosensitive resin coating at a region of the peripheral area; and
after the forming the opening at the implantation region and the opening at the region of the peripheral area, implanting ions into the semiconductor wafer.

2. The method according to claim 1, wherein a covering surface of the photosensitive resin coating, after the forming the opening at the region of the peripheral area, is smaller than a first threshold to reduce degassing of atoms of the photosensitive resin coating during the implantation of ions so that the pressure in the implantation chamber remains below a second threshold during this ion implantation.

3. The method according to claim 1, wherein the forming the opening at the implantation region of the integrated circuit area and the forming the opening at the region of the peripheral area are carried out simultaneously.

4. The method according to claim 1, wherein the covering surface of the photosensitive resin coating, after having formed the openings at the implantation region of the integrated circuit area and at the region of the peripheral area, is less than 75% of a total surface of the semiconductor wafer.

5. The method according to claim 1, wherein during the ion implantation, the ions are counted using a Faraday cup, the ion implantation ending when a number of counted ions reaches a threshold number.

6. The method according to claim 1, wherein the ion implantation dopes the region of the peripheral area and the implantation region of the integrated circuit area at a dose greater than or equal to 1×10¹⁵ atoms/cm².

7. A semiconductor device, comprising:
an integrated circuit area and a peripheral area around the integrated circuit area, the peripheral area comprising at least one doped region of a same doping characteristic as at least one doped implantation region of the integrated circuit area.

8. The device according to claim 7, wherein the at least one doped region of the peripheral area is devoid of electrical connections.

9. The device according to claim 7, wherein the at least one doped region of the peripheral area and the at least one implantation region of the integrated circuit area have a dopant concentration greater than or equal to 1×10²⁰ atoms/cm³.

10. A semiconductor wafer, comprising:
a first surface including an integrated circuit area and a peripheral area that surrounds the integrated circuit area;
a photosensitive resin on the first surface of the semiconductor wafer;
a first opening in the photosensitive resin at the integrated circuit area; and
a second opening in the photosensitive resin at the peripheral area.

11. The wafer according to claim 10, wherein a covering surface of the photosensitive resin is smaller than 75% of a total surface area of the first surface.

12. The wafer according to claim 10, wherein a first region in the integrated circuit area under the first opening includes a same doping of ions as a second region in the peripheral area under the second opening.

13. The wafer according to claim 10, wherein the second opening is ring-shaped.

14. The wafer according to claim 10, wherein the second opening surrounds the first opening.

15. The wafer according to claim 12, wherein the first region and the second region each include a doping concentration of ions greater than or equal to 1×10²⁰ atoms/cm³.

16. The wafer according to claim 10, wherein the peripheral area includes a dummy area, and the second opening is in the dummy area.

17. The wafer according to claim 10, wherein the peripheral area includes a seal ring area, and the second opening is in the seal ring area.

18. The wafer according to claim 10, wherein the peripheral area is devoid of electrical connections.
